(19) United States
(12) Patent Application Publication
(10) Pub. No.: US 2008/0157776 A1
(43) Pub. Date: Jul. 3, 2008

(54) MEASUREMENT OF ANALOG COIL VOLTAGE AND COIL CURRENT

(76) Inventors: Adil Jaffer, Markham (CA); Zhihong Mao, Stouffville (CA)

Correspondence Address: GENERAL ELECTRIC CO.;GLOBAL PATENT OPERATION, 187 Danbury Road, Suite 204, Wilton, CT, 06897-4122, US

(21) Appl. No.: 11/954,134

(22) Filed: Dec. 11, 2007

Related U.S. Application Data
(63) Continuation-in-part of application No. 11/617,048, filed on Dec. 28, 2006.

(51) Int. Cl. G01R 31/327

(52) U.S. Cl. 324/424

(57) ABSTRACT

A monitor circuit is provided which detects various incipient failure modes of a circuit breaker. The monitor circuit includes a processor and a primary circuit connected in circuit with the processor. The primary circuit may be configured for preventing transients and high currents associated with the operation of the circuit breaker from damaging the processor. A secondary circuit may be connected in circuit with the processor and the primary circuit. The secondary circuit provides an analog voltage input and a current input to the processor that is representative of an aspect of the circuit breaker and wherein the processor is configured to detect at least one failure mode of at least one circuit breaker from the analog voltage and current input.

### CROSS REFERENCE TO RELATED APPLICATIONS

This application is a continuation in part of U.S. patent application Ser. No. 11/617,048, entitled “Measurement of Analog Coil Voltage and Coil Current”, filed Dec. 28, 2006.

### BACKGROUND OF THE INVENTION:

Circuit breakers are widely used to protect electrical lines and equipment. The circuit breaker monitors current through an electrical conductor and trips to interrupt the current if certain criteria are met. One such criterion is the maximum continuous current permitted in the protected circuit. The maximum continuous current the circuit breaker is designed to carry is known as the frame rating. However, the breaker can be used to protect circuits in which the maximum continuous current is less than the circuit breaker frame rating, in which case the circuit breaker is configured to trip if the current exceeds the maximum continuous current established for the particular circuit in which it is used. This is known as the circuit breaker current rating. Obviously, the circuit breaker current rating can be less than but cannot exceed the frame rating.

Within conventional circuit breakers, the contact output of a protection relay within the breaker is connected to the coil of the breaker which in turn is used to trip the power line halting the flow of current through the circuit breaker to the load. The circuit breaker, which is often subject to harsh operating conditions such as vibrations, shocks, high voltages, and inductive load arcing is thus a critical device to the operation providing current flow to the ultimate load. Due to the harsh operating conditions that circuit breakers are subject to, above average failure rates are difficult to maintain, and manpower must be expended continuously to ensure the availability of the power system and power to the ultimate load. A signature analysis of the waveform of the current passing through the DC trip coil of a circuit breaker may be used to detect changes in the structure of the trip mechanism of the breaker. Normally the waveform of the trip coil current is highly repeatable, and a change in the waveform is often the initial sign that the mechanical characteristics of the trip mechanism or the electrical characteristics of the trip coil have changed.

Although there are dedicated devices designed to measure the circuit breaker coil voltage and current, there are no protective relays that measure the circuit breaker coil voltage and current and carry out a signature analysis in order to detect changes that indicate an evolving failure. Any prior work in the area of circuit protection of which we are aware has involved the use of digital detection of currents and voltages present in the contact output and, in this instance, the digital measurements were used to provide feedback on the correct operation of the contact input and had no impact on the diagnosis of breaker coil health.

### BRIEF DESCRIPTION OF THE INVENTION

In accordance with an embodiment of the invention, a monitor circuit is provided which detects various incipient failure modes of a circuit breaker. The monitor circuit comprises a processor and a primary circuit connected in circuit with the processor. The primary circuit may be configured for preventing transients and high currents associated with the operation of the circuit breaker from damaging the processor. A secondary circuit may be connected in circuit with the processor and the primary circuit. The secondary circuit provides an analog voltage input and a current input to the processor that is representative of an aspect of the circuit breaker and wherein the processor is configured to detect at least one failure mode of at least one circuit breaker from the analog voltage and current input.

### BRIEF DESCRIPTION OF THE DRAWINGS

Those skilled in the art will have a thorough and complete understanding of the invention from reference to the following figures and detailed description:

FIG. 1 depicts the coil signature wiring schematic according to the present invention;

FIG. 2 depicts a typical trip coil waveform according to the present invention;

FIG. 3 shows a block diagram of a monitor circuit in accordance with another embodiment of the present invention; and

FIG. 4 is a circuit diagram showing an opto-coupler circuit in accordance with the monitor circuit of FIG. 3.

### DETAILED DESCRIPTION OF THE INVENTION

In the following description of the improvements made to measure analog coil voltage and coil current to anticipate failure of a power system, it is noted that the contact output of a protection relay is used to trip a circuit breaker coil. This coil is an electromechanical solenoid that releases a stored-energy mechanism that acts to open or close the circuit breaker. During the energizing of the coil, the voltage across the coil, the current flowing through the coil, and the corresponding energy being dissipated will have a particular time characteristic. By analyzing the changes in these characteristics we have found it is possible to detect various incipient failure modes of the circuit breaker, and to signal to the user that preventative maintenance is required.

Through the use of transformer isolated DC-DC converters and analog optical isolation of the total system, these improvements are the first to incorporate this functionality directly within the contact output, by implementing isolated analog measurement of voltage and current through the contact output energizing the breaker coil.

The general shape of the waveform is that of a simple exponential with a time constant equal to the ratio of the inductance of the coil to the resistance of the coil. The initial slope of the waveform depends upon the ratio of the applied voltage to the initial inductance of the coil. The final value of the current depends upon the ratio of the applied voltage to the resistance of the coil. Because the trip coil contains a moving armature, the inductance of the coil changes with time and the waveform of the trip coil current is not exactly an exponential. The amount and timing of the deviation from a simple exponential is strongly dependent upon the details of the motion of the armature.

As indicated previously, a signature analysis of the waveform of the energy dissipated in the operating coil of a circuit breaker (i.e., the current through the DC trip coil) can be used to detect changes in the structure of the trip mechanism of the breaker. Normally the waveform of the trip coil current energy is highly repeatable, and a change in the waveform is often the initial sign that the mechanical characteristics of the trip mechanism or the electrical characteristics of the trip coil have changed. Thus, the coil signature element generates an alarm if the signature analysis results in a significant deviation for a particular coil operation. It is also possible to perform signature analysis of AC trip coil currents, but the analysis is complicated by the randomness in the timing of the energization of the coil relative to the phase angle of the applied voltage. Fortunately, most of the circuit breakers for utility applications use DC trip coils because batteries are used to supply control power to a substation.

As anticipated in the present invention, the coil signature element will also include a baseline feature. The coil signature element measures the maximum coil current, the duration of the coil current, and the minimum voltage during each coil operation. Averaged values of these measurements are calculated over multiple operations, allowing the user to create baseline values from the averaged values. The coil signature element will use these baseline values to determine if there has been a significant deviation in any value during a particular breaker coil operation.

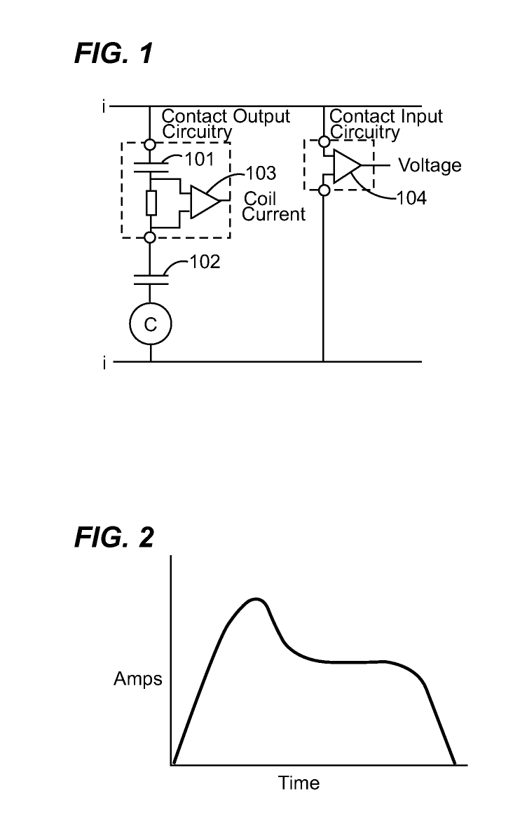

With respect to FIG. 1, there is shown a shown a coil signature wiring schematic, wherein the coil current is measured by a DC current monitor that has, preferably, been integrated into the contact output circuitry. A typical trip coil current waveform resulting from such a coil signature element schematic is shown in FIG. 2. As depicted, the coil signature element is able to produce the following measurements: coil energy (i.e., the product of coil voltage and coil current integrated over the duration of coil operation); current maximum (i.e., the maximum value of the coil current for a coil operation); current duration (i.e., the time which the coil current exceeds a precalibrated current level, preferably 0.25 amperes, during a coil operation); voltage minimum (i.e., the lowest value of the voltage during a coil operation); coil signature (i.e., the value of coil energy averaged over multiple operations); average current maximum (i.e., the maximum coil current averaged over multiple operations); average current duration (i.e., the coil current duration averaged over multiple operations); and average voltage minimum (i.e., the voltage minimum averaged over multiple operations).

More specifically, FIG. 1 depicts a coil circuit wiring schematic comprised of both a contact output circuitry and a contact input circuitry. Coil current is measured in the contact output circuitry by DC current monitor (103), and voltage is measured in the contact input circuitry by DV voltage monitor (104). Current reaching current monitor (103) first passes through relay contacts (101 and 102). It is preferred that the electrical output from the monitoring devices (103 and 104) are received by a microprocessor (not shown) after first passing through a linear opticoupler (not shown) as a means of electrically isolating the coil signature elements from the circuit breaker per se. The microprocessor is programmed to compute the values for the mathematical equations shown below.

The measurement of the coil current utilizing the coil signature device depicted in FIG. 1 is provided by the monitoring circuitry of the contact output that is used to energize the coil. Prior to energizing the coil, it is expected that there will be a voltage across the contact. When the coil is energized, this voltage will drop to zero. Therefore, this function will be triggered by a negative transition voltage operand associated with this contact output. Once triggered, the element will remain active for the period determined by the trigger duration setting.

With respect to FIG. 2, a typical trip coil current waveform is depicted wherein the general shape of the waveform, as stated above, is that of a simple exponential with a time constant equal to the ratio of the inductance of the coil to the resistance of the coil.

The signature analysis is performed for each operation of the circuit breaker by comparing the trip coil current waveform with the average waveform computed from all of the previous operations (i.e., a baseline value).

It is first necessary to establish the average waveform over many operations of the breaker, that is each time the breaker is operated, to capture and scale the current waveform:

V(τ)=v(tₛₜₐᵣₜ+τ)

I(τ)=i(tₛₜₐᵣₜ+τ)/i(t_{end})

P(τ)=V(τ)×I(τ)

In the above mathematic equation, “V” refers to voltage, “I” refers to amperes, “P” refers to power, and “τ” ranges from zero to the difference between the ending and starting time; the starting time being the moment when the current through the coil starts flowing. This is actually the starting time being the moment when the current through the coil becomes greater than 0.25 amps; and the ending time being the moment when the current becomes less than 0.25 amps. The difference between the ending time and the starting time is selected ahead of time by the user to capture the complete waveform. This scaling process somewhat compensates for variations in control voltage. Both the initial time rate of change of the current as well as its final value are proportional to the control voltage.

Next, the current signature is computed by simply adding all of the waveforms and dividing by the number of waveforms to obtain the mathematical mean:

$$\overline{I} ( τ ) = \frac{1}{N} {\sum }_{k = 1}^{N} {I}_{k} ( τ )$$

Similarly, the energy signature is calculated by adding all of the waveforms and dividing by the number of waveforms. In short, by substituting “P” for “I” in the above equation.

It is also necessary to estimate the square of the variability of the waveforms:

$${S}^{2} ( τ ) = \frac{1}{N - 1} {\sum }_{k = 1}^{N} {( I ( τ ) - \overline{I} ( τ ) )}^{2}$$

$${S}^{2} ( τ ) = \frac{1}{N - 1} {\sum }_{k = 1}^{N} {( P ( τ ) - \overline{P} ( τ ) )}^{2}$$

Finally, it is useful to estimate the net uncertainty squared, integrated over the time span of the waveforms:

$${U}^{2} = \frac{1}{{t}_{end} - {t}_{start}} {\int }_{0}^{{t}_{end} - {t}_{start}} {S}^{2} ( τ ) d τ$$

The reader should note that while in the preceding equations, the waveforms are treated as continuous functions, this is for explanatory purposes in better understanding the invention . It should be understood by those skilled in the art that in practice the waveforms are actually sampled and that the previous integral is computed numerically by taking the sum over the samples.

The procedure according to the present invention for detecting changes in the trip coil current waveform, is to actually to compute the deviation of the waveform from the signature, each time the breaker trips. That is, compute the deviation squared, integrated over the time span of the waveform:

$${D}^{2} = \frac{1}{{t}_{end} - {t}_{start}} {\int }_{0}^{{t}_{end} - {t}_{start}} {( P ( τ ) - \overline{P} ( τ ) )}^{2} d τ$$

In this equation. the designation “D” is a calculation of how far the trip coil current deviates from the signature. Whether or not the deviation is significant is determined by comparing D with a multiple of U, or by comparing D square with a multiple of U square. The multiple may depend on the desired confidence interval, and can be set using well known statistical properties of the normal distribution. For example, for a 99.7% confidence interval, a so-called 3-sigma interval, the multiplier is three, i.e., the deviation is deemed significant if D squared (or D²) is greater than 9 times U squared.

If the deviation is not significant, the new waveform is used to update the average and U squared. If it is significant, it is not used for an update and a significant deviation is declared meaning that the user may anticipate an evolving failure and that maintenance of the circuit breaker should be attended to or scheduled in the near future.

Thus, a coil signature alarm will be declared if:

D²>M²·U²

Wherein “M” is a value depending upon a predetermined confidence interval setting. More specifically, “M” is taken from the following table for the specific confidence interval setting by the user:

| Confidence Interval Setting | M |
|---|---|
| 0.990 | 2.5758 |
| 0.991 | 2.6121 |
| 0.992 | 2.6521 |
| 0.993 | 2.6968 |
| 0.994 | 2.7478 |
| 0.995 | 2.8070 |
| 0.996 | 2.8782 |
| 0.997 | 2.9677 |
| 0.998 | 3.0902 |
| 0.999 | 3.2905 |

In addition to the above, the coil signature element is able to produce the following measurements:
i. current maximum (i.e., the maximum value of the coil current for a coil operation):

Iₘₐₓ=max(I(τ))
ii. voltage minimum (i.e., the lowest value of the voltage during a coil operation);

Vₘᵢₙ=min(V(τ))
iii. current duration (i.e., the time which the coil current exceeds a precalibrated current level, preferably 0.25 amperes, during a coil operation);

Δt=t_{end}−tₛₜₐᵣₜ

The averaged values of these signals my then be calculated:
i. average current maximum (i.e., the maximum coil current averaged over multiple operations);

Īₘₐₓ = 1/N Σ^{N}_{k = 1}Īₘₐₓ

ii. average voltage minimum (i.e., the voltage minimum averaged over multiple operations):

av.Vₘᵢₙ=1/NΣₖ₌₁^{N}Vₘᵢₙ
iii. average current duration (i.e., the coil current duration averaged over multiple operations):

av.Δt=1/NΣₖ₌₁^{N}Δt

Once calculated, and if the established baseline is asserted, then:

I_{BASELINE}=I_{MAX}

Δt_{BASELINE}=av.Δt

A high current alarm will be preprogrammed at the time of manufacture to be declared indicating a potential failure of the circuit breaker, and to signal to the user that preventative maintenance is required if:

I_{MAX}>1.05·I_{BASELINE}

Similarly, a long current duration alarm will be declared if:

Δt>1.05·Δt_{BASELINE}

Similarly, a low voltage alarm will be declared if:

V_{MIN}<0.95·V_{BASELINE}

Such alarms may, of course, may be provided the user as visual, electronic, or audible signals indicating that the preprogrammed limits have been reached and exceeded.

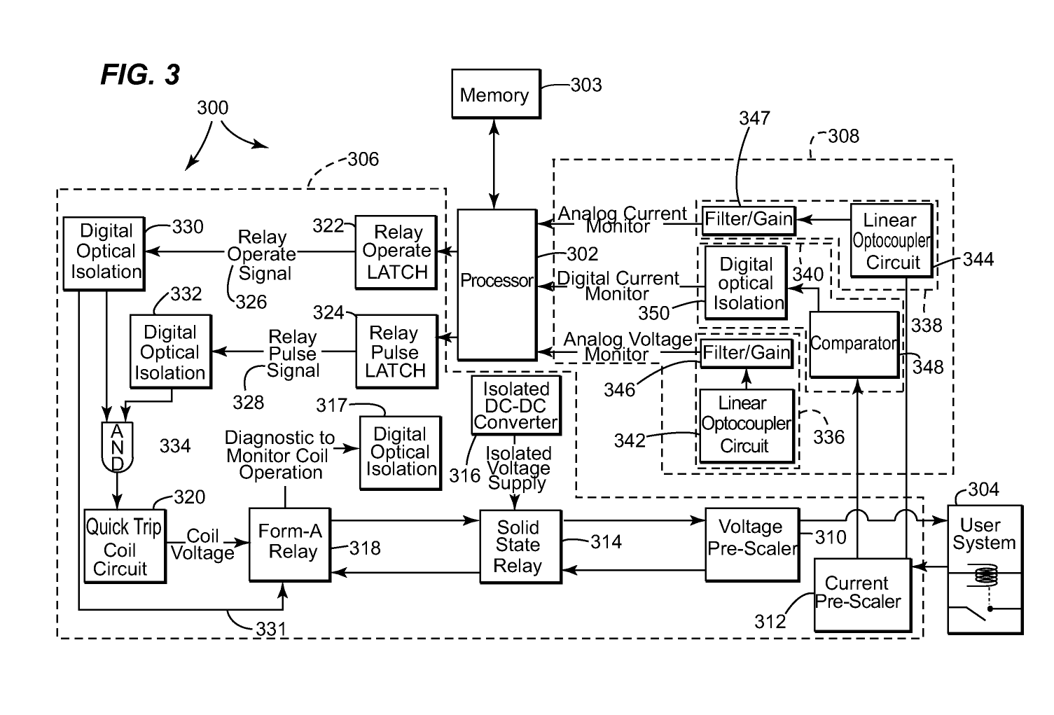

Referring now to FIG. 3, a monitor circuit in accordance with another aspect of the present invention is shown generally at 300. The monitor circuit 300 comprises a processor 302, and an associated memory 303, which may be configured via software or firmware as described above, e.g., to detect various incipient failure modes of at least one circuit breaker included in a user system 304 and, e.g., to signal to a user that preventative maintenance is required. The circuit 300 comprises a primary circuit 306 and a secondary circuit 308. The primary circuit is configured for preventing transients and high currents associated with the operation of the circuit breaker of the user system 304 from damaging the monitor circuit 300. The secondary circuit 308 provides an analog voltage input and a current input to the processor 302 that is representative of that across and through, respectively, of the circuit breaker coil of the user system 304. This analog voltage input and current input allows for the determination of various metrics related to the operation of the circuit breaker of the user system 304 such as current maximum, voltage minimum and current duration through each circuit breaker coil by the processor 302 for use, e.g., in anticipating failure of a circuit breaker as described above. The analog voltage and analog current measurement can also provide other data such as the average current and voltage as well as the maximum instantaneous power or total energy.

The primary circuit 306 is connected in circuit with the user system 304 via a voltage prescaler 310 and a current prescaler 312. Each of the prescalers 310 and 312 function to scale the input current and voltage to an appropriate level for use by the circuit 300 and to communicate the input voltage and current there between. The voltage prescaler 310 is in circuit with a solid state relay 314 and the secondary circuit 308.

The solid state relay (SSR) 314 is controlled by a relay pulse signal that is generated by the processor 302 in rapid response to a trip signal communicated to the processor from a main processor (not shown) of the user system 304. The SSR 314 is isolated from the processor through via a DC/DC converter 316 and a photo-transistor (not shown). The SSR 314 has two functions: to clamp an output voltage in under about 100 microseconds (μs) and to break large inductive loads that are beyond the breaking capacity of a Form-A relay 318. When the SSR is open (ie. not clamping the output voltage) the voltage prescaler 310 will measure the voltage that will be applied to the circuit breaker coil of the user system 304. When the SSR 314 is closed (ie clamping the output voltage) the current prescaler 312 will measure the current driving the external breaker coil.

To complement the SSR, a Form A relay 318 is connected in parallel to the user system 304 to provide an extended duration for the clamping of the output voltage. A quick trip circuit 320 is also employed to improve the operation time of the relay 318 (for example by less then about 4 milliseconds (ms)) by applying a relatively short higher voltage pulse to the relay coil that is then replaced with a lower continuous voltage. A diagnostic feedback, which includes digital optical isolation 317 comprising, e.g., a phototransistor, is provided from the relay 318 to the processor 302 to monitor for proper operation of the relay 318.

The processor 302 is connected in circuit with latches 322 and 324 to provide a relay out signal 326 and a relay pulse signal 328. The relay out signal 326 is generated to control operation of the relay 318 over a continuous period of time and the relay pulse signal 328 is generated to control operation of the SSR 314 for short term bursts during the initial tripping and the final release of the form-A relay 318. A As described in more detail below, a combined product of the relay pulse signal and the relay operation signal provides control for the quick trip circuit 320 which in turn is only active during the initial tripping of the form-A relay 318.

Optical isolators 330 and 332 comprising, e.g., photo-transistors (not shown), are provided in the circuit path to isolate the processor 302 from high transient current and voltage spikes. Additionally, an AND gate circuit 334 is provided for signaling when the quick trip circuit should be energized to provide the higher voltage to the relay based on the relay pulse 328. The function of the AND gate circuit 334 may be carried out via transistor logic (not shown). Lower voltage continuous operation of the relay 318 is controlled via a relay out signal 331 from the optical isolator 330 to the relay 318.

The secondary circuit 308 may comprise three legs, a breaker coil voltage leg 336, a breaker coil current leg 338 and minimum allowable current leg 340. The breaker coil voltage leg 336 and breaker coil current leg 338 comprises coil voltage and current necessary to determine current maximum and voltage minimum through a particular circuit breaker coil by the processor 302 as described above. The minimum allowable current leg 340 provides a feedback mechanism to the processor 302 in order to prevent the form-A relay 318 from breaking excessive currents (these currents are small and are not within the range of the analog current measurement provided by the current pre-scaler 312).

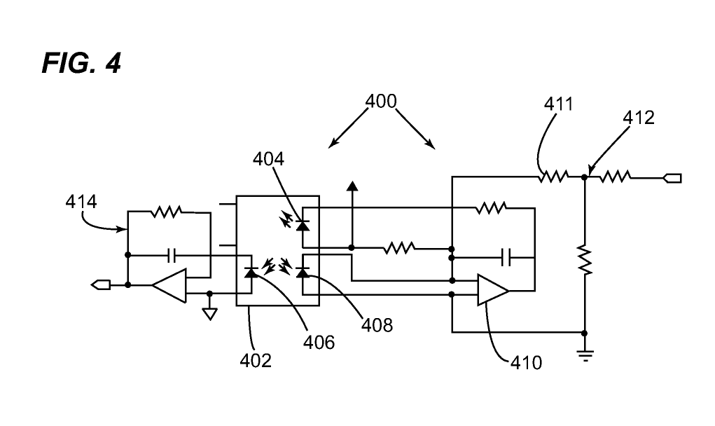

In accordance with another feature, each leg 336 and 338 comprises a linear opto-coupler circuit 342 and 344, respectively that are provided to isolate the processor 302 from the user system 304. As shown in FIG. 4, one exemplary linear opto-coupler circuit usable in the practice of the present invention is shown generally at 400. The linear opto-coupler circuit 400 comprises an opto-coupler 402 that includes a light emitting diode (LED) 404 that may comprise AlGaAs. The LED 404 may be configured to illuminate two photodiodes, that is, an output photodiode 406 and an input photodiode 408 each of which are closely matched in their response to the light emitted by the LED 404. The input photodiode 408 is used to monitor and stabilize, in conjunction with an operational amplifier 410, a light output of the LED 404. As a result, typical known nonlinearity and drift characteristics of the LED 404 are virtually eliminated. The output photodiode 406 produces a photocurrent that is linearly related to the current through a resistor 411. The output photodiode 406 produces a current that is furthermore converted into a corresponding voltage through the use of a post filter/amplifier circuit 414. The linear opto-coupler circuit 400 may also comprise a voltage divider input circuit 412 used to reduce voltage levels.

Referring again to FIG. 3, a double stage filter and gain circuit 346 may be provided for signal conditioning the breaker coil voltage in the leg 336 prior to input to the processor 302. A single stage filter and gain circuit 347 may be provided in the current leg 338.

The minimum allowable current leg 340 comprises a comparator 348 and a phototransistor 350. The comparator 348 may comprise a Schmidt Trigger circuit and reference(both not shown) whose output maybe used to drive a photodiode of the phototransister 350. The phototransistor 350 is also provided for isolation purposes.

In operation, upon energization of a circuit breaker coil of the user system 304, an initial current is picked up by the current prescaler 312 and output through the minimum allowable current leg 340 where it is converted to a digital signal to the processor 302. This initial current may be subject to a threshold of approximately 100 milliamps. The processor 302 is configured in response to receive the digital signal and to then provide a corresponding logic element which the user may use to prevent the relay 318 from releasing and breaking excessive currents. Upon receipt of a larger coil current, between approximately 1 ampere and approximately 30 amperes, the coil current leg 338 is energized with a scaled current which is then input to the processor 302 for determination of the current maximum, voltage minimum and current duration through a particular circuit breaker coil of the user system 304 by the processor 302 for use in anticipating failure of the particular circuit breaker.

While we have illustrated and described a preferred embodiment of this invention, it is to be understood that this invention is capable of variation and modification, and we therefore do not wish to be limited to the precise terms set forth, but desire to avail ourselves of such changes and alternations which may be made for adapting the invention to various usages and conditions. Accordingly, such changes and alterations are properly intended to be within the full range of equivalents, and therefore within the purview, of the following claims.

1. A monitor circuit for detecting various incipient failure modes of a circuit breaker, the monitor circuit comprising:
a processor;
a primary circuit connected in circuit with the processor and the primary circuit configured for preventing transients and high currents associated with the operation of the circuit breaker from damaging the processor; and
a secondary circuit connected in circuit with the processor and the primary circuit for providing an analog voltage input and a current input to the processor that is representative of an aspect of the circuit breaker;
wherein the processor is configured to detect at least one failure mode of at least one circuit breaker from the analog voltage input and current input.

2. The monitor circuit of claim 1, wherein the analog voltage input to the processor corresponds to a voltage across a circuit breaker coil of the at least one circuit breaker and wherein the current input to the processor corresponds to a current through the at least one circuit breaker coil.

3. The monitor circuit of claim 2, wherein the processor is further configured to determine a current maximum, a voltage minimum and a current duration from the analog voltage input and current input.

4. The monitor circuit of claim 2, wherein the primary circuit comprises a voltage prescaler and a current prescaler for scaling respective voltages and currents from the circuit breaker coil.

5. The monitor circuit of claim 1, wherein the primary circuit comprises:
a form relay connected in circuit with, and optically isolated from, the processor; and
a solid state relay also connected in circuit with, and optically isolated from, the processor;
wherein the form relay and the solid state relay are configured to prevent high currents and voltages from damaging the processor.

6. The monitor circuit of claim 5, wherein the primary circuit further comprises a quick trip circuit that is configured to boost an initial voltage to the form relay.

7. The monitor circuit of claim 5, wherein the secondary circuit comprises:
a breaker coil voltage leg connected in circuit with the voltage prescaler; and
a breaker coil current leg connected in circuit with the current prescaler.

8. The monitor circuit of claim 7, wherein each of the breaker coil voltage leg and the breaker coil current leg comprises a linear opto-coupler circuit.

9. The monitor circuit of claim 8, wherein the linear opto-coupler circuit comprises an opto-coupler that comprises:
a light emitting diode (LED) receiving input from either the breaker coil voltage or current leg;
an output photodiode being illuminatable by the LED; and
an input photodiode also being illuminatable by the LED and being configured to stabilize a light output of the LED;
wherein the output photodiode produces a photocurrent that is linearly related to the light output of the LED.

10. The monitor circuit of claim 9, wherein the linear opto-coupler circuit further comprises a voltage divider input circuit and a post amplifier/filter circuit.

11. The monitor circuit of claim 7, wherein the secondary circuit further comprises a minimum allowable current leg for use by the processor to prevent the form-A relay from breaking excessive currents.
